(19) United States
(12) Patent Application Publication
(10) Pub. No.: US 2008/0061849 A1
(43) Pub. Date: Mar. 13, 2008

(54) POWER-ON CIRCUIT

(76) Inventor: Mun Weon Ahn, Seoul (KR)

Correspondence Address: SHERR & NOURSE, PLLC, 620 HERNDON PARKWAY, SUITE 200, HERNDON, VA, 20170, US

(21) Appl. No.: 11/852,005

(22) Filed: Sep. 7, 2007

(30) Foreign Application Priority Data
Sep. 12, 2006 (KR) 10-2006-0088445

(51) Int. Cl. H03K 17/22

(52) U.S. Cl. 327/143

(57) ABSTRACT

A power-on circuit which may generate a power-on signal that is insensitive to the rising speed of an I/O voltage or core voltage. A power-on signal may be generated according to current drive capabilities of NMOS and PMOS transistors based on the I/O voltage or core voltage. A power-on circuit may control an I/O voltage when the level of a core voltage is lower than the I/O voltage.

The present application claims priority under 35 U.S.C. 119 to Korean Patent Application No. 10-2006-0088445 (filed on Sep. 12, 2006), which is hereby incorporated by reference in its entirety.

### BACKGROUND

A semiconductor chips may be subjected to a series of initialization procedures when being started up, which may include applying an external voltage the semiconductor chip. During startup, because the states of input/output (I/O) terminals of the chip are not known, a Retention Programmable Input Output (RPIO) scheme may be used to avoid a data collision with another system connected with the chip.

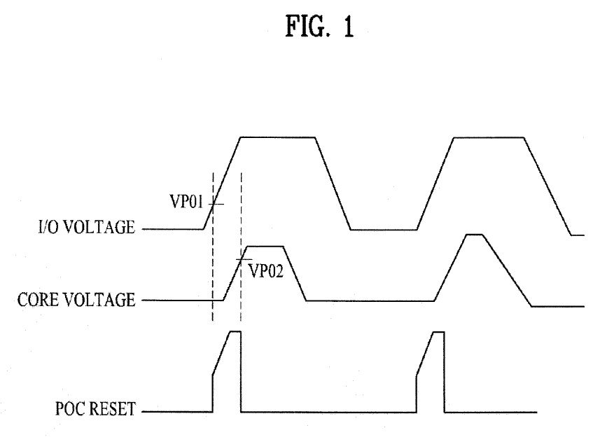

However, when an I/O voltage and a chip internal voltage (referred to hereinafter as a ‘core voltage’) are separately used in a RPIO scheme, there may be a need for a power-on circuit (POC). Example FIG. 1 illustrates a power-on circuit timing diagram that detects an I/O voltage, activates a reset signal at a specific level VPOC1 of the detected I/O voltage, detects a core voltage, and deactivates the reset signal at a specific level VPOC2 of the detected core voltage.

### SUMMARY

Embodiments relate to a power-on circuit which may generate a power-on signal that is insensitive to the rising speed of an I/O voltage or core voltage. A power-on signal may be generated according to current drive capabilities of NMOS and PMOS transistors based on the I/O voltage or core voltage, in accordance with embodiments. In embodiments, a power-on circuit may control an I/O voltage when the level of a core voltage is lower than the I/O voltage.

In embodiments, a power-on circuit may detect an I/O voltage and a core voltage and generate a power-on signal. Once a power-on signal is generated, the flow of current of the I/O voltage and core voltage may be blocked to prevent leakage current. In embodiments, a power-on circuit may generate a power-on signal based on current flow irrespective of ON/OFF states of an I/O voltage and core voltage.

In embodiments, a power-on circuit may include at least one of: An input/output (I/O) voltage detector that outputs an I/O voltage detect signal when an I/O voltage is applied; the I/O voltage detect signal may have a low level when the I/O voltage is lower than a detect voltage and a high level when the I/O voltage exceeds the detect voltage. A core voltage detector that outputs a core voltage detect signal when a core voltage is applied. A power-on signal generator which receives the I/O voltage detect signal and the core voltage detect signal and outputs a power-on signal

In embodiments, a power-on signal may have an I/O ground voltage level when the I/O voltage is lower than the detect voltage, an I/O voltage level when the I/O voltage exceeds the detect voltage, and the I/O ground voltage level based on the I/O voltage detect signal of the high level when the core voltage exceeds the detect voltage.

### DRAWINGS

Example FIG. 1 is a timing diagram of a power-on circuit.

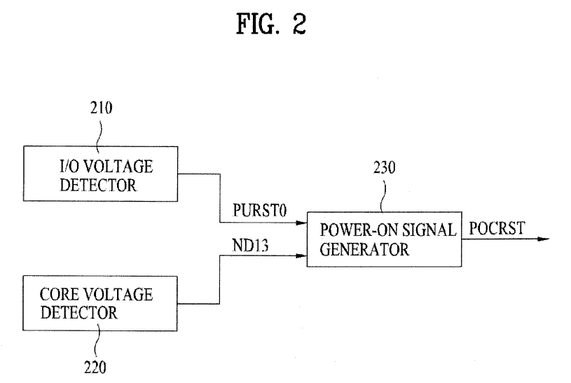

Example FIG. 2 is a block diagram illustrating the configuration of a power-on circuit, according to embodiments.

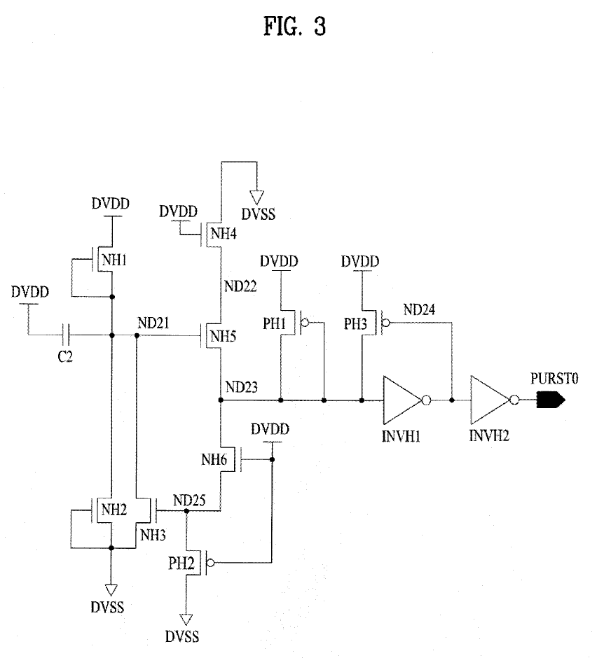

Example FIG. 3 is a circuit diagram of an I/O voltage detector, according to embodiments.

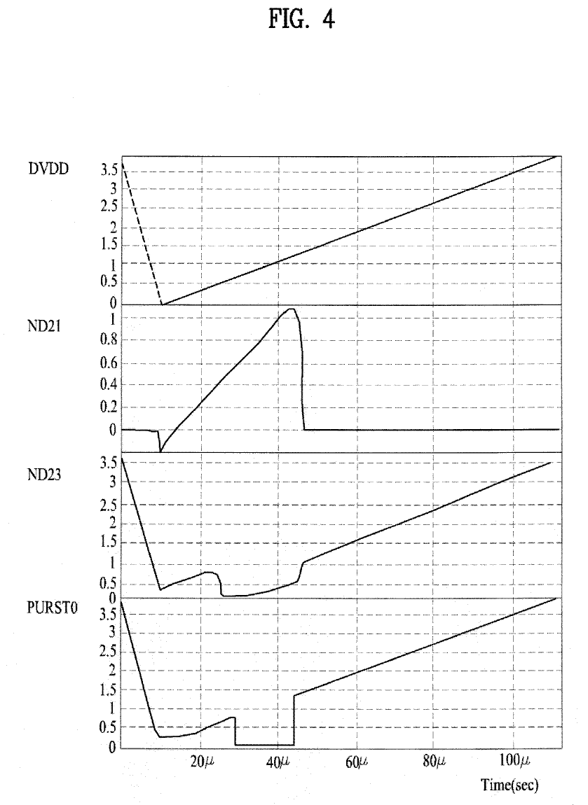

Example FIG. 4 is a timing diagram of an I/O voltage detector, according to embodiments.

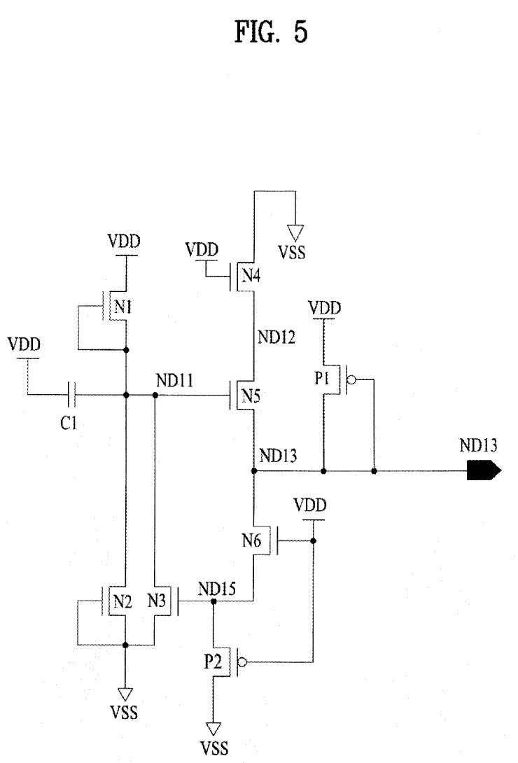

Example FIG. 5 is a circuit diagram of a core voltage detector, according to embodiments.

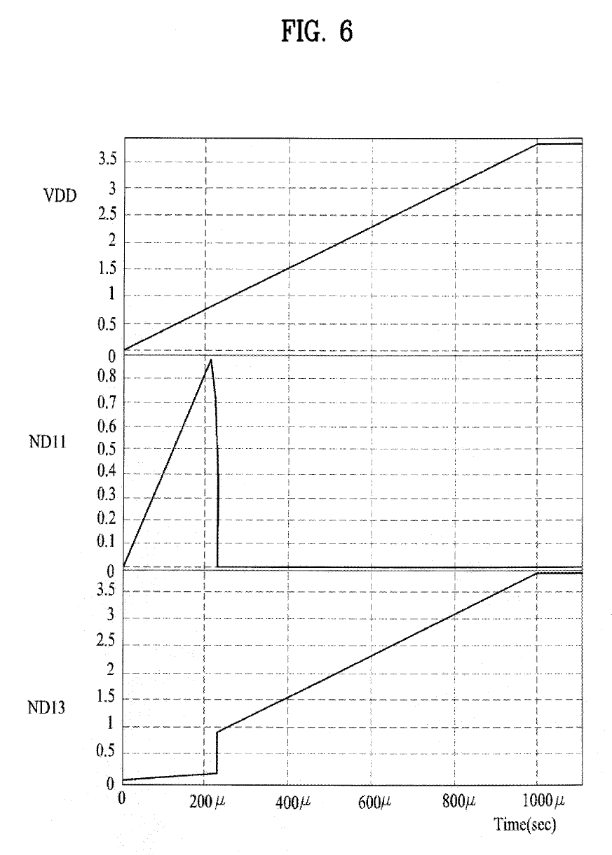

Example FIG. 6 is a timing diagram of a core voltage detector, according to embodiments.

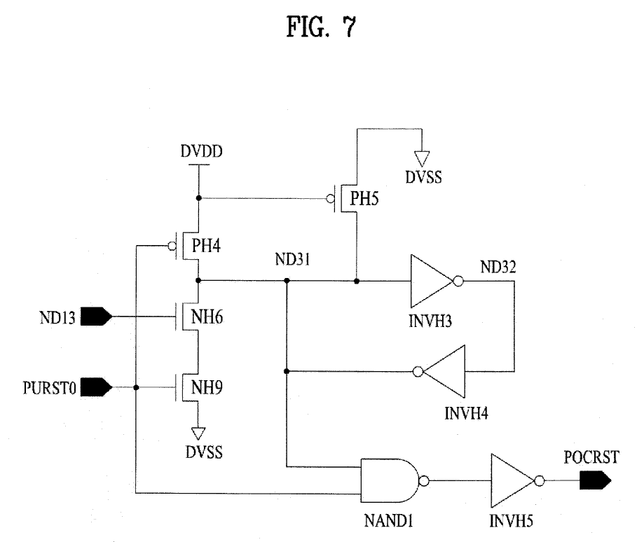

Example FIG. 7 is a circuit diagram of a power-on signal generator, according to embodiments.

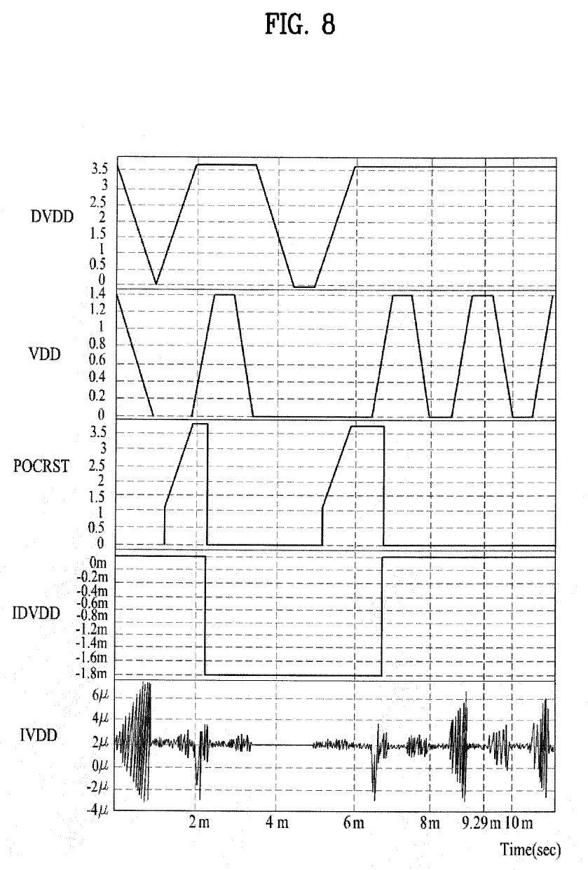

Example FIG. 8 is a timing diagram of a power-on circuit, according to embodiments.

### DESCRIPTION

As illustrated in example FIG. 2, a power-on circuit, in accordance with embodiments, may include at least one of: An input/output (I/O) voltage detector 210 which outputs an I/O voltage detect signal PURST0 in response to an I/O voltage DVDD. A core voltage detector 220 which outputs a core voltage detect signal ND13 in response to a core voltage VDD. A power-on signal generator 230 which receives the I/O voltage detect signal PURST0 and the core voltage detect signal ND13 and outputs a power-on signal POCRST in response to PURST0 and ND13.

Example FIG. 3 is an example circuit diagram of I/O voltage detector 210, in accordance with embodiments. I/O voltage detector 210 may include capacitor C2, which may raise a voltage at the gate terminal (node ND21) of fifth n-channel metal oxide semiconductor (NMOS) transistor NH5 as the I/O voltage DVDD is applied. I/O voltage detector 210 may include fifth NMOS transistor NH5, which may receive the voltage raised by the capacitor C2 at the gate terminal to selectively connect nodes ND22 and ND23 when the received voltage exceeds the threshold voltage of fifth NMOS transistor NH5. I/O voltage detector 210 may include a fourth NMOS transistor NH4, which may receive I/O voltage DVDD at the gate terminal to selectively apply I/O ground voltage DVSS to node ND22 when I/O voltage DVDD exceeds the threshold voltage of fourth NMOS transistor NH4.

I/O voltage detector 210 may include first p-channel metal oxide semiconductor (PMOS) transistor PH1, which may have a source terminal connected to I/O voltage DVDD and a gate and drain terminals commonly connected to node ND23 to selectively apply I/O voltage DVDD to the node ND23 when the threshold voltage of first PMOS transistor PH1 is exceeded. I/O voltage detector 210 may include a sixth NMOS transistor NH6, which may selectively apply the voltage at node ND23 to node ND25 in response to I/O voltage DVDD. I/O voltage detector 210 may include a second PMOS transistor PH2, which may prevent a voltage at the node ND25 from having too high of a level when the I/O voltage DVDD is initially applied. I/O voltage detector 21 may include third NMOS transistor NH3, which may turn off fifth NMOS transistor NH5, which may prevent leakage current as I/O voltage DVDD is applied.

I/O voltage detector 210 may include first inverter INVH1, which may receive the voltage at node ND23 as I/O voltage DVDD is applied. Second inverter INVH2 may receive the output of first inverter INVH1 and output I/O voltage detect signal PURST0. Third PMOS transistor PH3 may raise the voltage at node ND23 to the I/O voltage DVDD when the voltage at node ND23 becomes too low. First NMOS transistor NH1 and second NMOS transistor NH2 may remove noise or abnormal voltage when noise is present in I/O voltage DVDD or an abnormal voltage is applied. Accordingly, I/O voltage detector 210 may output I/O voltage detect signal PURST0. However, one of ordinary skill in the art would appreciate other circuit confirmations for I/O voltage detector 210 to output an output I/O voltage detect signal.

In embodiments, I/O voltage detector 210 may operate as follows:

1) As I/O voltage DVDD is applied, the voltage at node ND21 is raised by capacitor C2, as shown in an I/O voltage detector timing diagram of FIG. 4.

2) When the voltage at node ND21 exceeds the threshold voltage of fifth NMOS transistor NH5, the fifth NMOS transistor NH5 is turned on.

3) Fourth NMOS transistor NH4 is turned on in response to I/O voltage DVDD to apply I/O ground voltage DVSS to node ND23, as shown in the I/O voltage detector timing diagram of FIG. 4. As a result, I/O voltage detect signal PURST0 having a low level is output through first inverter INVH1 and second inverter INVH2.

4) When I/O voltage DVDD exceeds the threshold voltage of first PMOS transistor PH1, first PMOS transistor PH1 is turned on, to raise the voltage at node ND23, as shown in the I/O voltage detector timing diagram of FIG. 4. As a result, I/O voltage detect signal PURST0 having a high level is output from the time that I/O voltage DVDD exceeds a detect voltage.

5) The raised voltage at node ND23 is transferred to the node ND25 through sixth NMOS transistor NH6, where sixth NMOS transistor NH6 is turned on in response to I/O voltage DVDD, to raise the voltage at node ND25.

6) Third NMOS transistor NH3 is turned on by the raised voltage at node ND25, which transfers I/O ground voltage DVSS to node ND21, which causes fifth NMOS transistor NH5 to be turned off.

7) Because fifth NMOS transistor NH5 is turned off and the voltage at node ND23 is at a high level, a low-level voltage is output at a node ND24 through first inverter INVH1. This low-level voltage is input into the gate terminal of third PMOS transistor PH3, which raises the voltage at node ND23 to I/O voltage DVDD.

8) Sixth NMOS transistor NH6 is turned on in response to I/O voltage DVDD, which may prevent (in embodiments) the problem that in an initial state, the voltage at node ND23 becomes a high level, thus turning on third NMOS transistor NH3 and turning off fifth NMOS transistor NH5, which may prevent generation of I/O voltage detect signal PURST0.

9) Second PMOS transistor PH2 may prevent the voltage at node ND25 from becoming too high in the initial state of the circuit, which may prevent (in embodiments) the problem that in an initial state, the voltage at node ND25 becomes too high, thus turning on third NMOS transistor NH3 and turning off the fifth NMOS transistor NH5, which may prevent generation of I/O voltage detect signal PURST0.

10) First and second NMOS transistors NH1 and NH2 may remove noise in I/O voltage DVDD or an abnormal voltage.

Example FIG. 5 is an example circuit diagram of core voltage detector 220, in accordance with embodiments. Core voltage detector 220 may include capacitor C1, which may raise a voltage at gate terminal (node ND11) of fifth NMOS transistor N5 as core voltage VDD is applied, in accordance with embodiments. Core voltage detector 220 may include fifth NMOS transistor N5, which may receive the voltage raised by capacitor C1 at the gate terminal of fifth NMOS transistor N5. Fifth NMOS transistor N5 may selectively connect nodes ND12 and ND13 to each other when the received voltage exceeds the threshold voltage of fifth NMOS transistor N5. Core voltage detector 220 may include fourth NMOS transistor N4, which may receive core voltage VDD at the gate terminal. Fourth NMOS transistor N4 may selectively apply core ground voltage VSS to node ND12 when the received core voltage VDD exceeds the threshold voltage of the fourth NMOS transistor N4.

First PMOS transistor P1 may have a source terminal connected to core voltage VDD. First PMOS transistor P1 may have a gate terminal and drain terminal connected in common to node ND13 to transfer core voltage VDD to the node ND13 when the threshold voltage of first PMOS transistor P1 is exceeded. Sixth NMOS transistor N6 may transfer the voltage at node ND13 to node ND15 in response to core voltage VDD applied to the gate of sixth NMOS transistor N6. Second PMOS transistor P2 may prevent a voltage at node ND15 from becoming too high when the core voltage VDD is initially applied. Third NMOS transistor N3 may turn off fifth NMOS transistor N5 to prevent leakage current as the core voltage VDD is applied. First NMOS transistor N1 and second NMOS transistor N2 remove noise and abnormal voltage, when noise is present in the core voltage VDD or an abnormal voltage is applied. In embodiments, core voltage detector 220 may output core voltage detect signal ND13. However, one of ordinary skill in the art will appreciate other circuit configurations of core voltage detector 220.

In embodiments, core voltage detector 220 may operate as follows:

1) As core voltage VDD is applied to core voltage detector 220, the voltage at node ND11 may be increased by capacitor C1, as illustrated in the core voltage detector timing diagram of FIG. 6.

2) When the voltage at node ND11 exceeds the threshold voltage of fifth NMOS transistor N5, fifth NMOS transistor N5 is turned on.

3) When fourth NMOS transistor N4 is turned on in response to core voltage VDD, core voltage detect signal ND may be output at a low level, as illustrated in the core voltage detector timing diagram of FIG. 6.

4) When core voltage VDD exceeds the threshold voltage of first PMOS transistor P1, first PMOS transistor P1 is turned on, which may cause the core voltage detect signal ND13 at a high level to be output, as shown in the core voltage detector timing diagram of FIG. 6.

5) The raised voltage at node ND13 is transferred to node ND15 through sixth NMOS transistor N6, where sixth NMOS transistor N6 is turned on in response to core voltage VDD, which raises the voltage at node ND15.

6) Third NMOS transistor N3 is turned on by the raised voltage at node ND15 to apply core ground voltage VSS to node ND11, causing fifth NMOS transistor N5 to be turned off.

7) Sixth NMOS transistor N6 may be turned on in response to core voltage VDD, which may remove the problem (in embodiments) that at the initial state, the voltage at node ND13 becomes too high, thus turning on third NMOS transistor N3 and turning off fifth NMOS transistor N5, which may inadvertently preventing generation of core voltage detect signal ND13.

8) Second PMOS transistor P2 prevents the voltage at node ND15 from becoming too high at the initial state, which may prevent the problem (in embodiments) that the voltage at node ND15 becomes too high at the initial state, thus turning on third NMOS transistor N3 and turning off fifth NMOS transistor N5, which may in advertently prevent core voltage detect signal ND13.

9) First NMOS transistor N1 and second NMOS transistor N2 may remove noise in core voltage VDD or an abnormal voltage.

Example FIG. 7 is an example circuit diagram of power-on signal generator 230, in accordance with embodiments. Power-on signal generator 230 may include fourth PMOS transistor PH4m which may a high voltage at node ND31 when I/O voltage detect signal PURST0 is at a low level. The gate of ninth NMOS transistor NH9 may be connected to I/O voltage detect signal PURST0. The gate of an eighth NMOS transistor NH8 may be connected to core voltage detect signal ND13. Third inverter INVH3 and fourth inverter INVH4 may constitute a latch to latch the voltage at node ND31. NAND gate NAND1 may receive the latched voltage at node ND31 and I/O voltage detect signal PURST0. Fifth PMOS transistor PH5 may make the voltage at node ND31 low at the initial state to initialize the state of latch. In embodiments, fifth inverter INVH5 may receive the output of NAND gate NAND1 and output power-on signal POCRST. However, one of ordinary skill in the art would appreciate other circuit configurations of power-on signal generator 230.

In embodiments, power-on signal generator 230 may operate as follows:

1) When I/O voltage DVDD is lower than a detect voltage, I/O voltage detect signal PURST0 having a low level is input into the gate of fourth PMOS transistor PH4, thus making the voltage at node ND31 high. This high-level voltage at node ND31 is input into NAND gate NAND1 together with the I/O voltage detect signal PURST0 having a low level. As a result, power-on signal POCRST of I/O ground voltage DVSS level is output, as shown in the power-on circuit timing diagram of FIG. 8.

2) When I/O voltage DVDD exceeds the detect voltage, I/O voltage detect signal PURST0 of a high level is input into the gate of fourth PMOS transistor PH4, thus turning off fourth PMOS transistor PH4. Accordingly, the voltage at node ND31 is latched to a high level by third inverter INVH3 and fourth inverter INVH4. I/O voltage detect signal PURST0 at a high level is input into NAND gate NAND1, so that power-on signal POCRST of I/O voltage DVDD is output, as shown in power-on circuit timing diagram of FIG. 8.

3) When core voltage VDD exceeds the detect voltage, core voltage detect signal ND13 at core voltage VDD is input into the gate of sixth NMOS transistor NH6, thus turning on sixth NMOS transistor NH6. At this time, I/O voltage detect signal PURST0, which is already at a high level, is input into the gate of ninth NMOS transistor NH9, turning on ninth NMOS transistor NH9. As a result, the voltage at node ND31 is changed from latched high level voltage to the I/O ground voltage DVSS low level voltage. This low level voltage of I/O ground voltage DVSS level at node ND31 is input into NAND gate NAND1, so that the power-on signal POCRST having an I/O ground voltage DVSS level is output, as shown in the power-on circuit timing diagram of FIG. 8.

Embodiments relate to a power-on circuit that generates a power-on signal insensitive to the rising speed of an I/O voltage and/or core voltage, according to current drive capabilities of NMOS and PMOS transistors based on the I/O voltage or core voltage. In embodiments, a power-on circuit may be capable of controlling the I/O voltage with the level of the core voltage, which is lower than the I/O voltage, and blocking the flow of currents of the I/O voltage and core voltage to prevent leakage current. In embodiments, a power-on circuit may be capable of generating a power-on signal based on a current flow irrespective of ON/OFF states of the I/O voltage and core voltage. In embodiments, because the transistors used do not have a large W/L ratio, it is possible to miniaturize the power-on circuit.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising a power-on circuit, wherein the power-on circuit comprises:
an input/output (I/O) voltage detector;
a core voltage detector; and
a power-on signal generator, wherein the output of the power-on signal generator is a function of the output of the input/output (I/O) voltage detector and the output of the core voltage detector.

2. The apparatus of claim 1, wherein the input/output (I/O) voltage detector inputs an I/O voltage and outputs an I/O voltage detect signal as a function of the I/O voltage.

3. The apparatus of claim 2, wherein the I/O voltage detect signal has a low level when the I/O voltage is lower than a detect voltage and the I/O voltage detect signal has a high level when the I/O voltage exceeds the detect voltage.

4. The apparatus of claim 1, wherein the core voltage detector inputs a core voltage and outputs a core voltage detect signal.

5. The apparatus of claim 1, wherein:
the power-on signal generator inputs a I/O voltage detect signal from the input/output (I/O) voltage detector;
the power-on signal generator inputs a core voltage detect signal from the core voltage detector; and
the power-on signal generator outputs a power-on signal as a function of the I/O voltage detect signal and the core voltage detect signal.

6. The apparatus of claim 5, wherein:
the power-on signal has an I/O ground voltage level when an I/O voltage is lower than a detect voltage;
the power-on signal has the I/O voltage level when the I/O voltage exceeds the detect voltage; and
the power-on signal has the I/O ground voltage level as a function of if the I/O voltage detect signal has a high level when a core voltage exceeds the detect voltage.

7. The apparatus of claim 1, wherein the input/output (I/O) voltage detector comprises two inverters which receive a voltage detected at an I/O voltage detect node and output a voltage at an I/O voltage level or an I/O ground voltage level.

8. The apparatus of claim 7, wherein the input/output (I/O) voltage detector comprises a p-channel metal oxide semiconductor (PMOS) transistor having a source connected to the I/O voltage and a gate and drain terminal commonly connected to the I/O voltage detect node, wherein the p-channel metal oxide semiconductor (PMOS) transistor is turned on to transfer the I/O voltage detected signal having a high level to the I/O voltage detect node when the I/O voltage exceeds a threshold voltage of the PMOS transistor.

9. The apparatus of claim 1, wherein the core voltage detector comprises an n-channel metal oxide semiconductor (NMOS) transistor which applies a core ground voltage to a first node when a received core voltage exceeds a threshold voltage of the NMOS transistor.

10. The apparatus of claim 9, wherein the core voltage detector comprises a PMOS transistor having a source terminal connected to the core voltage and a gate terminal and drain terminal connected in common to a second node, wherein the PMOS transistor applies the core voltage to the second node when a threshold voltage of the PMOS transistor is exceeded.

11. The apparatus of claim 1, wherein the power-on signal generator comprises a PMOS transistor having a gate terminal that receives an I/O voltage detect signal.

12. The apparatus of claim 11, wherein the power-on signal generator comprises a first NMOS transistor having a gate terminal that receives the I/O voltage detect signal.

13. The apparatus of claim 12, wherein the power-on signal generator comprises a second NMOS transistor having a source terminal connected to a drain terminal of the first NMOS transistor, a drain terminal connected to a drain terminal of the PMOS transistor, and a gate terminal that receives a core voltage detect signal.

14. The apparatus of claim 13, wherein the power-on signal generator comprise two inverters that receive the I/O voltage detect signal and the core voltage detect signal through the first NMOS transistor and the second NMOS transistor.

15. The apparatus of claim 14, wherein the two inverters latching a voltage at a common output node of the PMOS transistor, the first NMOS transistor, and the second NMOS transistors.

16. The apparatus of claim 15, wherein the power-on signal generator comprises a NAND gate that receives a voltage output from the core voltage detector and the I/O voltage detect signal to output a power-on signal.
